(19) United States
(12) Patent Application Publication
(10) Pub. No.: US 2015/0349280 A1
(43) Pub. Date: Dec. 3, 2015

(54) GLASS SUBSTRATE FOR ORGANIC EL DEVICE, AND ORGANIC EL DEVICE USING SAME

(71) Applicant: Nippon Electric Glass Co., Ltd., Shiga (JP)

(72) Inventors: Atsushi MUSHIAKE, Shiga (JP); Tomoki YANASE, Shiga (JP); Takako TOJYO, Shiga (JP); Takashi MURATA, Shiga (JP)

(21) Appl. No.: 14/372,314

(22) PCT Filed: Jan. 17, 2013
(86) PCT No.: PCT/JP2013/050797

§ 371 Date: Jul. 15, 2014

(30) Foreign Application Priority Data
Jan. 18, 2012 (JP) 2012-007629

(51) Int. Cl. H01L 51/00; H01L 51/52

(52) U.S. Cl. CPC H01L 51/0096; H01L 51/5268; H01L 51/5275; H01L 2251/303

(57) ABSTRACT

Provided is a glass substrate for an OLED device, including a roughened surface having a surface roughness Rt of 50 to 10,000 nm as at least one surface thereof, the glass substrate for an OLED device having a refractive index nd of 1.55 or more.

### TECHNICAL FIELD

The present invention relates to a glass substrate for an OLED device and an OLED device using the glass substrate for an OLED device.

### BACKGROUND ART

An organic electroluminescence element (OLED element) is light and thin and can be driven at low power consumption, and hence its application for a planar light-emitting illumination device has attracted much attention. The OLED element is manufactured by forming a transparent electrode layer on a surface of a translucent substrate (glass substrate), forming an organic light-emitting layer formed of an OLED material on a surface of the transparent electrode layer, and forming a counter electrode on a surface of the organic light-emitting layer. Then, when a voltage is applied between the transparent electrode layer and the counter electrode, light emitted in the organic light-emitting layer passes through the transparent electrode layer and the translucent substrate and is extracted to the outside.

However, part of the light emitted in the organic light-emitting layer is totally reflected owing to a difference in refractive index at the interface between the organic light-emitting layer and the glass substrate and a difference in refractive index at the interface between the glass substrate and air, and thus is confined inside the OLED element. For example, in the case of using an organic light-emitting material having a refractive index nd of 1.9 and a glass substrate having a refractive index nd of 1.5, light to be extracted to the outside of the OLED element accounts for about 20 to 25% of the total light emitted in the organic light-emitting layer.

As means for suppressing deterioration of light extraction efficiency, studies have been made on a method involving increasing a refractive index of a glass substrate to match the refractive index of the glass substrate to that of an organic light-emitting layer, and providing a transparent resin sheet having an uneven shape on a surface of the glass substrate. When the glass substrate and the transparent resin sheet as described above are used, light emitted in the organic light-emitting layer can be efficiently extracted to the outside.

### SUMMARY OF INVENTION

### Technical Problem

In general, thermosetting resins such as polyimide are each used for the transparent resin sheet. However, it is not easy to form an uneven shape in a surface of any such resin, resulting in the problem of significantly increasing the production cost of an OLED device.

As means for enhancing light extraction efficiency, it may be possible to form an uneven shape physically in a surface of a glass substrate. However, the physical formation of an uneven shape in a surface of a glass substrate may cause a problem in that the glass substrate is easily broken by a physical impact in a production process of an OLED element.

The present invention has been made in view of the above-mentioned problems. A technical object of the present invention is to invent a glass substrate for an OLED device that is not easily broken by a physical impact and can exhibit enhanced light extraction efficiency even without using any transparent resin sheet.

### Solution to Problem

The inventors of the present invention have made extensive studies and have consequently found that the above-mentioned technical object can be achieved by restricting the refractive index of a glass substrate within a predetermined range and strictly restricting the surface shape of the glass substrate. Thus, the finding is proposed as the present invention. That is, a glass substrate for an OLED device of the present invention has a refractive index nd of 1.55 or more and comprises a roughened surface having a surface roughness Rt of 50 to 10,000 nm as at least one surface thereof.

Herein, the “refractive index nd” can be measured by a commercially available refractometer (for example, KPR-2000, a refractometer manufactured by Kalnew Optical Industrial Co., Ltd.). It is possible to use, as a measurement sample, for example, a cuboid sample measuring 25 mm by 25 mm by about 3 mm thick produced by cutting out glass substrates each having a size of 25 mm square by dicing, and then laminating the glass substrates in a state in which an immersion liquid having a refractive index nd matched with that of the glass substrates is saturated between the glass substrates. Further, when the glass substrate is thin and has the shape of a glass film, it is possible to use, as a measurement sample, for example, a cuboid sample measuring 25 mm by 25 mm by about 3 mm thick produced by cutting out a plurality of glass films each having a size of 25 mm square by using a laser scriber, and then laminating the glass films in a state in which an immersion liquid having a refractive index nd matched with that of the glass films is saturated between the glass films. The “surface roughness Rt” refers to a value measured by a method in conformity with JIS R0601 (2001). The “OLED device” includes an OLED illumination device and the like.

The glass substrate for an OLED device of the present invention has a refractive index nd of 1.55 or more. With this, a difference in refractive index between an organic layer and the glass substrate is smaller, and hence the amount of light to be confined inside the organic light-emitting layer owing to total reflection thereof can be reduced. As a result, the light extraction efficiency of an OLED device can be enhanced. The refractive index nd is preferably 1.6 or more, particularly preferably 1.7 or more.

Further, the glass substrate for an OLED device of the present invention comprises a roughened surface having a surface roughness Rt of 50 to 10,000 nm as at least one surface thereof. With this, light in the glass substrate can be scattered, and hence the amount of light confined in the glass substrate can be reduced. As a result, the light extraction efficiency of an OLED device can be enhanced.

Second, a glass substrate for an OLED device of the present invention has a refractive index nd of 1.55 or more and comprises a roughened surface having a surface roughness RSm of 0.01 to 1,000 μm as at least one surface thereof. Herein, the “surface roughness RSm” refers to a value measured by a method in conformity with JIS R0601:2001. When the surface roughness RSm of the roughened surface is restricted to 0.01 to 1,000 μm, light in the glass substrate can be scattered, and hence the amount of light to be confined in the glass substrate can be reduced. As a result, the light extraction efficiency of an OLED device can be enhanced.

Third, a glass substrate for an OLED device of the present invention has a refractive index nd of 1.55 or more and comprises a roughened surface having a surface roughness ratio Rt/RSm of 0.01 to 1 as at least one surface thereof. When the surface roughness ratio Rt/RSm of the roughened surface is restricted to 0.01 to 1, light in the glass substrate can be scattered, and hence the amount of light to be confined in the glass substrate can be reduced. As a result, the light extraction efficiency of an OLED device can be enhanced.

Fourth, in the glass substrate for an OLED device of the present invention, it is preferred that the roughened surface be formed only as one surface and another surface opposite to the roughened surface have a surface roughness Rt of 10 nm or less. Herein, the term “surface roughness Rt” refers to a value measured by a method in conformity with JIS R0601 (2001). With this, the quality of a transparent electrode made of indium tin oxide (ITO) or the like can be enhanced.

Fifth, in the glass substrate for an OLED device of the present invention, it is preferred that the roughened surface be formed by physical roughening treatment. With this, roughening treatment can be uniformly applied to the surface of the glass substrate in a short time.

Sixth, in the glass substrate for an OLED device of the present invention, it is preferred that the physical roughening treatment include sandblasting treatment. With this, roughening treatment can be uniformly applied to a surface of a glass substrate with a large area in a short time. A blasting material to be used in the sandblasting has a grain size of preferably #200 to #4,000, #200 to #2,000, #200 to #1,500, particularly preferably #200 to #1,200. When the grain size of the blasting material is too large, it is difficult to control the surface roughnesses Rt and RSm within each proper range, and hence it is difficult to enhance the light extraction efficiency. On the other hand, when the grain size of the blasting material is too small, the surface roughnesses Rt and RSm of the roughened surface are too large, with the result that the in-plane strength of the glass substrate is liable to reduce.

Seventh, in the glass substrate for an OLED device of the present invention, it is preferred that the physical roughening treatment include polishing treatment. With this, roughening treatment can be uniformly applied to the surface of the glass substrate in a short time. A polishing material to be used in the polishing treatment has a grain size of preferably #220 to #3,000, #300 to #2,000, #400 to #1,500, particularly preferably #400 to #1,200. When the grain size of the polishing material is too large, it is difficult to control the surface roughnesses Rt and RSm within each proper range, and hence it is difficult to enhance the light extraction efficiency. On the other hand, when the grain size of the polishing material is too small, the surface roughnesses Rt and RSm of the roughened surface are too large, with the result that the in-plane strength of the glass substrate is liable to reduce.

Eighth, in the glass substrate for an OLED device of the present invention, it is preferred that the roughened surface be formed by the physical roughening treatment, followed by chemical solution treatment. With this, microcracks produced by the roughening treatment or the like can be removed, and hence the in-plane strength of the glass substrate can be enhanced. A chemical solution preferably comprises one kind or two or more kinds selected from the group consisting of HF, HCl, H₂SO₄, HNO₃, NH₄F, NaOH, and NH₄HF₂, and particularly preferably is a mixed solution of HF and NH₄F or a mixed solution of NH₄F and NH₄HF₂. Each of those chemical solutions has good reactivity with glass, and thus can remove properly the microcracks produced by the roughening treatment or the like.

The roughening treatment can be uniformly applied to a glass substrate with a large area by performing, for example, sandblasting. However, the sandblasting results in production of many microcracks in the roughened surface, and hence the glass substrate is liable to be broken by a physical impact in a production process of an OLED device. Further, as a glass substrate has a higher refractive index, the roughened surface is liable to have microcracks from the standpoint of the skeleton structure of glass. Thus, when the chemical solution treatment is applied to the roughened surface, such problem is likely to be overcome.

Each of those chemical solutions is used at a temperature of preferably 10 to 40° C., 15 to 35° C., particularly preferably 20 to 30° C. When the chemical solution treatment is performed at a temperature of more than 40° C., the chemical solution is liable to evaporate, possibly causing a safety problem and an environmental problem. On the other hand, when the chemical solution treatment is performed at a temperature of less than 10° C., the speed of the reaction between glass and the chemical solution becomes too slow, with the result that the production efficiency of the glass substrate is liable to deteriorate.

Ninth, in the glass substrate for an OLED device of the present invention, it is preferred that the chemical solution treatment comprise chemical solution treatment with an acid.

Tenth, in the glass substrate for an OLED device of the present invention, it is preferred that the glass substrate for an OLED device comprise 30 to 70 mass % of SiO₂ as a glass composition.

Eleventh, the glass substrate for an OLED device of the present invention has an in-plane strength of preferably 150 MPa or more, 300 MPa or more, 500 MPa or more, particularly preferably 1,000 MPa or more. With this, the glass substrate is not easily broken by a physical impact in a production process of an OLED device. Herein, the term “in-plane strength” refers to a value measured by a ring-on-ring test. The ring-on-ring test is performed in, for example, the following manner. First, a glass substrate (whose roughened surface side is positioned downward) is placed on a ring-shaped jig with a diameter of 25 mm. Subsequently, a jig with a diameter of 12.5 mm is used to press the glass substrate from the upper side. Specific conditions for the test are as follows: loading machine: strength tester manufactured by Shimadzu Corporation; loading rate: 0.5 mm/min; and press position: center. Finally, the fracture load at which the glass substrate is broken is calculated as the in-plane strength.

Twelfth, the glass substrate for an OLED device of the present invention is preferably used for an illumination device.

Thirteenth, an OLED device of the present invention comprises the above-mentioned glass substrate for an OLED device.

### BRIEF DESCRIPTION OF DRAWINGS

FIG. 1 is a schematic view illustrating an example of an OLED device according to an embodiment of the present invention.

### DESCRIPTION OF EMBODIMENTS

A glass substrate for an OLED device according to an embodiment of the present invention has a refractive index nd of 1.55 or more and comprises a roughened surface as one surface thereof. Note that each of both the surfaces of the glass substrate may be formed as a roughened surface.

The roughened surface has a surface roughness Rt of 50 to 10,000 nm. When the surface roughness Rt of the roughened surface is too small, light reflection hardly occurs at the roughened surface, and hence it is difficult to enhance the light extraction efficiency. In consideration of the light extraction efficiency, the roughened surface has a surface roughness Rt of preferably 300 nm or more, particularly preferably 500 nm or more. On the other hand, when the surface roughness Rt of the roughened surface is too large, the in-plane strength of the glass substrate is liable to reduce. In consideration of the in-plane strength of the glass substrate, the roughened surface has a surface roughness Rt of preferably 9,000 nm or less, particularly preferably 8,000 nm or less.

Further, the roughened surface has a surface roughness RSm of 0.1 to 1,000 μm. When the surface roughness RSm of the roughened surface is too small, light reflection hardly occurs at the roughened surface, and hence it is difficult to enhance the light extraction efficiency. In consideration of the light extraction efficiency, the roughened surface has a surface roughness RSm of preferably 1 μm or more, particularly preferably 5 μm or more. On the other hand, when the surface roughness Rt of the roughened surface is too large, the in-plane strength of the glass substrate is liable to reduce. In consideration of the in-plane strength of the glass substrate, the roughened surface has a surface roughness RSm of preferably 500 μm or less, particularly preferably 300 μm or less.

The roughened surface has a surface roughness ratio Rt/RSm of 0.01 to 1. When the surface roughness ratio Rt/RSm is too small, the glass substrate becomes wavy owing to insufficient roughening treatment, resulting in insufficient light extraction efficiency. In consideration of the light extraction efficiency, the surface roughness ratio Rt/RSm is preferably 0.03 or more, particularly preferably 0.05 or more. On the other hand, when the surface roughness ratio Rt/RSm is too large, the in-plane strength of the glass substrate is liable to reduce. In consideration of the in-plane strength of the glass substrate, the surface roughness ratio Rt/RSm is preferably 0.5 or less, particularly preferably 0.1 or less.

As a method for the roughening treatment, there are given polishing treatment, sandblasting treatment, atmospheric-pressure plasma treatment, and repressing treatment. Note that those methods for the roughening treatment are merely examples. In the present invention, the formation of a roughened surface as a surface of a glass substrate using any other technique is not inhibited.

When atmospheric-pressure plasma treatment is employed as the roughening treatment, the necessity for performing a washing step afterwards is obviated, and hence the production cost can be reduced. As an etching gas to be used for the atmospheric-pressure plasma treatment, there are given, for example: a rare gas such as He, Ar, or Xe; a perfluorocarbon gas such as CF₄, C₂F₆, or C₄F₈; a hydrofluorocarbon gas such as CHF₃ or CH₂F₂; a chlorofluorocarbon gas such as CCl₂F₂ or CHClF₂; a fluorocarbon gas such as CBrF₃ or CF₃I; an organic halogen gas free of F, such as CCl₄ or COCl₂; an inorganic halogen gas such as Cl₂, BCl₃, SF₆, NF₃, HBr, or SiCl₄; a hydrocarbon gas such as CH₄ or C₂H₆; and any other gas (e.g., O₂, H₂, N₂, or CO).

In the glass substrate for an OLED device according to this embodiment, it is preferred that the other surface opposite to the roughened surface be an unpolished surface. The surface opposite to the roughened surface has a surface roughness Rt of preferably 10 nm or less, less than 10 nm, 5 nm or less, 3 nm or less, particularly preferably 1 nm or less. When the surface opposite to the roughened surface is an unpolished surface, the glass substrate is hardly broken. Further, when the surface roughness Rt of the surface opposite to the roughened surface is smaller, the quality of an ITO film formed on the surface improves, and hence the uniformity of the distribution of an in-plane electric field can be easily maintained. As a result, in-plane luminance unevenness hardly occurs. Note that a resin sheet has inferior surface smoothness, and hence it is difficult to enhance the quality of an ITO film.

The glass substrate for an OLED device according to this embodiment preferably comprises 30 to 70 mass % of SiO₂ as a glass composition. SiO₂ is a component that forms a network of glass. However, when the content of SiO₂ is too large, meltability and formability deteriorate, and a refractive index becomes too small, with the result that it is difficult to match the refractive index with that of an organic light-emitting layer. On the other hand, when the content of SiO₂ is too small, vitrification hardly occurs, chemical resistance deteriorates, and an in-plane strength is liable to reduce.

The glass substrate for an OLED device according to this embodiment preferably comprises as a glass composition, in terms of mass %, 30 to 70% of SiO₂, 0 to 20% of Al₂O₃, 0 to 15% of Li₂O+Na₂O+K₂O, 5 to 55% of MgO+CaO+SrO+BaO, 0 to 20% of TiO₂, and 0 to 15% of ZrO₂. With this, the refractive index and the in-plane strength can be increased. The following description shows the reason why the content range of each component is defined as described above. Note that the term “Li₂O+Na₂O+K₂O” refers to the total content of Li₂O, Na₂O, and K₂O, and the term “MgO+CaO+SrO+BaO” refers to the total content of MgO, CaO, SrO, and BaO.

SiO₂ is a component that forms a network of glass. The content of SiO₂ is preferably 30 to 70%. When the content of SiO₂ is too large, meltability and formability deteriorate, and a refractive index becomes too small, with the result that it is difficult to match the refractive index with that of the organic light-emitting layer. On the other hand, when the content of SiO₂ is too small, vitrification hardly occurs, chemical resistance deteriorates, and an in-plane strength is liable to reduce.

Al₂O₃ is a component that forms a network of glass and is also a component that increases weather resistance. The content of Al₂O₃ is preferably 0 to 20%. When the content of Al₂O₃ is too large, a refractive index becomes too small, with the result that it is difficult to match the refractive index with that of the organic light-emitting layer. In addition, devitrified crystals are liable to precipitate in glass, with the result that it is difficult to perform the forming of the glass by an overflow down-draw method or the like.

B₂O₃ is a component that forms a network of glass. The content of B₂O₃ is preferably 0 to 20%. When the content of B₂O₃ is too large, chemical resistance deteriorates, and a refractive index becomes too small, with the result that it is difficult to match the refractive index with that of an organic light-emitting layer. In addition, devitrified crystals are liable to precipitate in glass, with the result that it is difficult to perform the forming of the glass by an overflow down-draw method or the like.

The content of Li₂O+Na₂O+K₂O is preferably 0 to 15%, 0 to 10%, particularly preferably 0 to 5%. When the content of Li₂O+Na₂O+K₂O is too large, thermal shock resistance deteriorates, and acid resistance reduces, with the result that the glass substrate is liable to be broken by an acid in an ITO patterning process.

Li₂O is a component that enhances meltability and formability and is also a component that improves devitrification resistance. The content of Li₂O is preferably 0 to 10%, particularly preferably 0 to 5%. When the content of Li₂O is too large, thermal shock resistance deteriorates, and acid resistance reduces, with the result that the glass substrate is liable to be broken by an acid in an ITO patterning process.

Na₂O is a component that enhances meltability and formability and is also a component that improves devitrification resistance. The content of Na₂O is preferably 0 to 10%, particularly preferably 0 to 5%. When the content of Na₂O is too large, thermal shock resistance deteriorates, and acid resistance deteriorates, with the result that the glass substrate is liable to be broken by an acid in an ITO patterning process.

K₂O is a component that enhances meltability and formability and is also a component that improves devitrification resistance. The content of K₂O is preferably 0 to 10%, particularly preferably 0 to 5%. When the content of K₂O is too large, thermal shock resistance deteriorates, and acid resistance deteriorates, with the result that the glass substrate is liable to be broken by an acid in an ITO patterning process.

MgO+CaO+SrO+BaO is a component that enhances meltability and formability. However, when the content of MgO+CaO+SrO+BaO is too large, devitrification resistance is liable to deteriorate. Thus, the content of MgO+CaO+SrO+BaO is preferably 5 to 55%, 15 to 50%, particularly preferably 20 to 45%.

MgO is a component that enhances meltability and formability. However, when the content of MgO is too large, devitrification resistance is liable to deteriorate. Thus, the content of MgO is preferably 0 to 20%.

CaO is a component that enhances meltability and formability. However, when the content of CaO is too large, devitrification resistance is liable to deteriorate. Thus, the content of CaO is preferably 0 to 20%, 1 to 15%, particularly preferably 3 to 12%.

SrO is a component that enhances meltability and formability and increases a refractive index. However, when the content of SrO is too large, devitrification resistance is liable to deteriorate. Thus, the content of SrO is preferably 0 to 25%, 0.1 to 20%, particularly preferably 1 to 15%.

BaO is a component that enhances meltability and formability and increases a refractive index. However, when the content of BaO is too large, devitrification resistance is liable to deteriorate. Thus, the content of BaO is preferably 0 to 45%, 5 to 40%, particularly preferably 15 to 35%.

TiO₂ is a component that increases a refractive index. However, when the content of TiO₂ is too large, glass is liable to be colored, devitrification resistance is liable to deteriorate, and a density is liable to increase. Thus, the content of TiO₂ is preferably 0 to 20%, 0.1 to 15%, particularly preferably 1 to 7%.

ZrO₂ is a component that increases a refractive index. However, when the content of ZrO₂ is too large, devitrification resistance excessively deteriorates in some cases. Thus, the content of ZrO₂ is preferably 0 to 15%, 0.001 to 10%, particularly preferably 1 to 7%.

In addition to the above-mentioned components, for example, the following components may be added.

ZnO is a component that enhances meltability and formability. However, when the content of ZnO is too large, devitrification resistance is liable to deteriorate. Thus, the content of ZnO is preferably 0 to 20%, particularly preferably 0 to 5%.

Rare-earth oxides such as Nb₂O₅, La₂O₃, and Gd₂O₃ are components that increase a refractive index. However, the rare-earth oxides themselves are expensive as raw materials. Further, when the rare-earth oxides are added in a glass composition in large amounts, devitrification resistance deteriorates in some cases. Thus, the total content of the rare-earth oxides is preferably 0 to 25%, particularly preferably 3 to 15%. Note that the content of Nb₂O₅ is preferably 0 to 15%, particularly preferably 0.1 to 12%. The content of La₂O₃ is preferably 0 to 15%, particularly preferably 3 to 12%. The content of Gd₂O₃ is preferably 0 to 15%, particularly preferably 0 to 10%.

As a fining agent, one kind or two or more kinds selected from the group consisting of As₂O₃, Sb₂O₃, SnO₂, CeO₂, F, SO₃, and Cl may be added at 0.001 to 3%. Note that it is feared that As₂O₃ and Sb₂O₃ may affect the environment, and hence the content of each of the components is preferably less than 0.1%, particularly preferably less than 0.01%. Further, CeO₂ is a component that lowers a transmittance, and hence the content thereof is preferably less than 0.1%, particularly preferably less than 0.01%. Besides, F is a component that deteriorates formability, and hence the content thereof is preferably less than 0.1%, particularly preferably less than 0.01%. In consideration of the foregoing, the fining agent is preferably one kind or two or more kinds selected from the group consisting of SnO₂, SO₃, and Cl. The total content of the components is preferably 0.001 to 3%, 0.001 to 1%, 0.01 to 0.5%, more preferably 0.05 to 0.4%.

PbO is a component that increases a refractive index. However, it is feared that PbO may affect the environment. Thus, the content of PbO is preferably less than 0.1%.

The glass substrate for an OLED device according to this embodiment is preferably formed by an overflow down-draw method. Herein, the term “overflow down-draw method”, which is also referred to as “fusion method”, refers to a method in which molten glass is caused to overflow from both sides of a heat-resistant trough-shaped structure, and the overflowing molten glasses are subjected to down-draw downward at the lower end of the trough-shaped structure while being joined, to thereby produce a glass substrate. With this, an unpolished glass substrate having good surface quality can be formed. This is because, in the case of the overflow down-draw method, the surfaces that should serve as the surfaces of the glass substrate are formed in the state of a free surface without being brought into contact with a trough-shaped refractory. The structure and material of the trough-shaped structure are not limited as long as a desired size and surface quality can be realized. Further, a method of applying a force to glass so that the down-draw is conducted downward is not particularly limited as long as a desired size and surface quality can be realized. For example, it may be possible to adopt a method in which glass is drawn while a heat-resistant roll having a sufficiently large width is rotated in contact with the glass. It may be possible to adopt a method in which glass is drawn while a plurality of pairs of heat-resistant rolls are brought into contact with only the vicinity of the edge surface of the glass.

The glass substrate for an OLED device according to this embodiment is also preferably formed by a slot down-draw method. The slot down-draw method can enhance the dimensional accuracy of the glass substrate as the overflow down-draw method can. Note that the slot down-draw method can form a roughened surface as a surface of the glass substrate by changing the shape of a slot.

In addition to the overflow down-draw method and the slot down-draw method, any of various methods may be adopted as a method of forming the glass substrate for an OLED device according to this embodiment. For example, a float method, a roll-out method, or a re-draw method may be adopted. In particular, when the glass substrate is formed by a float method, a large glass substrate can be manufactured at low cost.

In the glass substrate for an OLED device according to this embodiment, as the thickness becomes smaller, a lighter OLED device can be easily produced and the glass substrate can have more increased flexibility. Thus, the thickness is preferably 2 mm or less, 1.5 mm or less, 1 mm or less, particularly preferably 0.7 mm or less. On the other hand, when the thickness is too small, the glass substrate is liable to be broken, and hence the thickness of the glass substrate is preferably 50 μm or more, 100 μm or more, particularly preferably 200 μm or more. The glass substrate in the shape of a glass film has a possible minimum curvature radius of preferably 200 mm or less, 150 mm or less, 100 mm or less, 50 mm or less, particularly preferably 30 mm or less. Note that, as the possible minimum curvature radius of the glass substrate becomes smaller, the glass substrate has better flexibility, and hence the degree of freedom in installing an OLED lighting device or the like increases.

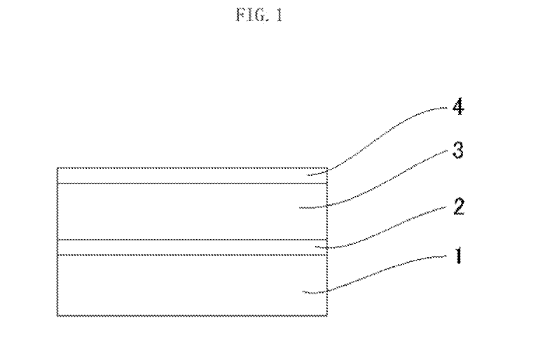

Hereinafter, an example of an OLED device according to an embodiment of the present invention is described with reference to FIG. 1.

The above-mentioned glass substrate for an OLED device is used as a glass substrate 1.

As a transparent electrode layer 2, there may be given, for example, a thin film made of ITO, indium zinc oxide (IZO), tin oxide, or a metal such as Au, a conductive polymer, a conductive organic material, a dopant (donor or acceptor)-containing organic material, a mixture of a conductor and a conductive organic material (including a polymer), and a laminate thereof. The transparent electrode layer 2 is usually formed by a vapor-phase growth method such as a sputtering method or an ion plating method. The thickness of the transparent electrode layer 2 is not particularly limited but is preferably about 50 to 300 nm.

As an OLED material for forming an organic light-emitting layer 3, there are given, for example: anthracene, naphthalene, pyrene, tetracene, coronene, perylene, phthaloperylene, naphthaloperylene, diphenylbutadiene, tetraphenylbutadiene, coumarin, oxadiazole, bisbenzoxazoline, bisstyryl, cyclopentadiene, coumarin, oxadiazole, bisbenzoxazoline, bisstyryl, cyclopentadiene, a quinoline metal complex, a tris(8-hydoxyquinolinato)aluminum complex, a tris(4-methyl-8-quinolinato)aluminum complex, a tris(5-phenyl-8-quinolinato)aluminum complex, an aminoquinoline metal complex, a benzoquinoline metal complex, tri-(p-terphenyl-4-yl)amine, pyran, quinacridone, rubrene, and derivatives thereof, an 1-aryl-2,5-di(2-thienyl)pyrrole derivative, a distyrylbenzene derivative, a styrylarylene derivative, a styrylamine derivative, and a compound or polymer having a group formed of any of these light-emitting compounds as part of its molecule. In addition to compounds derived from fluorochromes typified by the above-mentioned materials, it is also possible to use suitably the so-called phosphorescent light-emitting material, for example, a light-emitting material such as an Ir complex, an Os complex, a Pt complex, or a europium complex, and a compound or polymer having any of them in its molecule. A suitable material selected, if necessary, from those materials can be used.

As a material for a counter electrode 4, there are given, for example, aluminum, tin, magnesium, indium, calcium, gold, silver, copper, nickel, chromium, palladium, platinum, a magnesium-silver alloy, a magnesium-indium alloy, and an aluminum-lithium alloy. Of those, aluminum is preferred. The thickness of the counter electrode 4 is preferably 10 to 1,000 nm, 30 to 500 nm, particularly preferably 50 to 300 nm. The counter electrode 4 may be formed by a vacuum film forming process such as vapor deposition or sputtering.

Between the transparent electrode layer 2 and the organic light-emitting layer 3, a conductive polymer, a hole-injecting layer, and a hole-transporting layer can be further laminated. Between the organic light-emitting layer 3 and the counter electrode 4, an electron-injecting layer and an electron-transporting layer can be further laminated. Further, other known layers than those layers may be applied.

### EXAMPLES

Hereinafter, the present invention is described by way of Examples. Note that Examples below are merely illustrative. The present invention is by no means limited to Examples below.

<Experiment on Sample No. 1>

First, a glass substrate having the glass composition (No. 1) described in Table 1 and having a thickness of 0.7 mm was prepared. Subsequently, mirror polishing or the roughening treatment (alumina polishing or sandblasting) described in Table 1 was applied to the air-side surface of the glass substrate, followed by the post-processing described in Table 1, yielding Samples A, B, and C.

TABLE 1

| | | No. 1 | | | No. 2 | | | No. 3 | | |
|---|---|---|---|---|---|---|---|---|---|---|
| | | A | B | C | D | E | F | G | H | I |
| Glass | SiO₂ | 34.1 | 34.1 | 34.1 | 37.6 | 37.6 | 37.6 | 45 | 45 | 45 |
| composition | Al₂O₃ | 2 | 2 | 2 | 1.5 | 1.5 | 1.5 | 5 | 5 | 5 |
| (wt %) | CaO | 5.9 | 5.9 | 5.9 | 6 | 6 | 6 | 6 | 6 | 6 |
| | SrO | 4.9 | 4.9 | 4.9 | 5 | 5 | 5 | 5 | 5 | 5 |
| | BaO | 27 | 27 | 27 | 27 | 27 | 27 | 26 | 26 | 26 |
| | La₂O₃ | 4.3 | 4.3 | 4.3 | 4 | 4 | 4 | 6 | 6 | 6 |
| | ZrO₂ | 3.2 | 3.2 | 3.2 | 3 | 3 | 3 | 3 | 3 | 3 |
| | TiO₂ | 9.7 | 9.7 | 9.7 | 7 | 7 | 7 | 4 | 4 | 4 |
| | Nb₂O₅ | 8.9 | 8.9 | 8.9 | 8.9 | 8.9 | 8.9 | — | — | — |

| | | | | | | | | | |
|---|---|---|---|---|---|---|---|---|---|
| nd | 1.74 | 1.74 | 1.74 | 1.71 | 1.71 | 1.71 | 1.63 | 1.63 | 1.63 |
| Mirror polishing or | Mirror | #1,000 | #600 | Mirror | #1,000 | #400 | Mirror | #1,000 | #360 |
| roughening treatment | polishing | Alumina | Sandblasting | polishing | Alumina | Sandblasting | polishing | Alumina | Sandblasting |
| | | polishing | | | polishing | | | polishing | |
| Post-processing | HF | HF | HF | HF | HF | HF | HF | HF | HF |
| | treatment | treatment | treatment | treatment | treatment | treatment | treatment | treatment | treatment |
| Rt (μm) | <1 | 5.2 | 6.5 | <1 | 4.7 | 5.8 | <1 | 5.1 | 7.6 |
| RSm (μm) | 33 | 48 | 46 | 37 | 60 | 66 | 41 | 65 | 67 |
| Light extraction | 97% | 115% | 120% | 99% | 110% | 116% | 99% | 111% | 113% |
| efficiency | | | | | | | | | |
| In-plane strength | 1,450 | 900 | 1,200 | 1,500 | 1,000 | 1,100 | 1,400 | 1,200 | 1,050 |
| (MPa) | | | | | | | | | |

Mirror polishing was applied to Sample A by using a cerium-based polishing material having a grain size of #4,000. Alumina polishing was applied to Sample B by using alumina having a grain size of #1,000. Sandblasting was applied to Sample C by blowing, at 2 MPa, a blasting material (prepared by dispersing 4 kg of Al₂O₃ in 20 L of water) having a grain size of #600 onto a surface of the glass substrate.

Next, each of Samples A to C was immersed in an aqueous solution of 5 mass % HF at 25° C. for 30 minutes to perform HF treatment. After the HF treatment, a transparent electrode layer ITO (having a thickness of 100 nm) was formed by vapor deposition on the surface to which roughening treatment had not been applied. After that, predetermined patterning was carried out by using a photomask and hydrochloric acid. Subsequently, a conductive polymer PEDOT-PSS, a hole-transporting layer α-NPD (having a thickness of 60 nm), an organic light-emitting layer also serving as an electron-transporting layer Alq3 (having a thickness of 50 nm), an electron-injecting layer LiF (having a thickness of 1 nm), and a counter electrode Al (having a thickness of 100 nm) were formed, followed by sealing with a metal cap, thus manufacturing each OLED light-emitting device.

<Experiment on Sample No. 2>

First, a glass substrate having the glass composition (No. 2) described in Table 1 and having a thickness of 0.5 mm was prepared. Subsequently, mirror polishing or the roughening treatment (alumina polishing or sandblasting) described in Table 1 was applied to the air-side surface of the glass substrate, followed by the post-processing described in Table 1, yielding Samples D, E, and F.

Mirror polishing was applied to Sample D by using a cerium-based polishing material having a grain size of #4,000. Alumina polishing was applied to Sample E by using alumina having a grain size of #1,000. Sandblasting was applied to Sample F by blowing, at 2 MPa, a blasting material (prepared by dispersing 4 kg of Al₂O₃ in 20 L of water) having a grain size of #400 onto a surface of the glass substrate.

Next, each of Samples D to F was immersed in an aqueous solution of 5 mass % HF at 25° C. for 30 minutes to perform HF treatment. After the HF treatment, a transparent electrode layer ITO (having a thickness of 100 nm) was formed by vapor deposition on the surface to which roughening treatment had not been applied. After that, predetermined patterning was carried out by using a photomask and hydrochloric acid. Subsequently, a conductive polymer PEDOT-PSS, a hole-transporting layer α-NPD (having a thickness of 60 nm), an organic light-emitting layer also serving as an electron-transporting layer Alq3 (having a thickness of 50 nm), an electron-injecting layer LiF (having a thickness of 1 nm), and a counter electrode Al (having a thickness of 100 nm) were formed, followed by sealing with a metal cap, thus manufacturing each OLED light-emitting device.

<Experiment on Sample No. 3>

First, a glass substrate having the glass composition (No. 3) described in Table 1 and having a thickness of 1.0 mm was prepared. Subsequently, mirror polishing or the roughening treatment (alumina polishing or sandblasting) described in Table 1 was applied to the air-side surface of the glass substrate, followed by the post-processing described in Table 1, yielding Samples G, H, and I.

Mirror polishing was applied to Sample G by using a cerium-based polishing material having a grain size of #4,000. Alumina polishing was applied to Sample H by using alumina having a grain size of #1,000. Sandblasting was applied to Sample F by blowing, at 2 MPa, a blasting material (prepared by dispersing 4 kg of Al₂O₃ in 20 L of water) having a grain size of #360 onto a surface of the glass substrate.

Next, each of Samples G to I was immersed in an aqueous solution of 5 mass % HF to perform HF treatment under the conditions of 25° C. and 30 minutes. After the HF treatment, a transparent electrode layer ITO (having a thickness of 100 nm) was formed by vapor deposition on the surface to which roughening treatment had not been applied. After that, predetermined patterning was carried out by using a photomask and hydrochloric acid. Subsequently, a conductive polymer PEDOT-PSS, a hole-transporting layer α-NPD (having a thickness of 60 nm), an organic light-emitting layer also serving as an electron-transporting layer Alq3 (having a thickness of 50 nm), an electron-injecting layer LiF (having a thickness of 1 nm), and a counter electrode Al (having a thickness of 100 nm) were formed, followed by sealing with a metal cap, thus manufacturing each OLED light-emitting device.

<Experiment on Sample No. 4>

First, a glass substrate having the glass composition (No. 4) described in Table 2 and having a thickness of 1.8 mm was prepared. Subsequently, mirror polishing or the roughening treatment (alumina polishing or sandblasting) described in Table 2 was applied to the air-side surface of the glass substrate, followed by the post-processing described in Table 2, yielding Samples J, K, and L.

TABLE 2

| | | No. 4 | | | No. 5 | | |
|---|---|---|---|---|---|---|---|
| | | J | K | L | M | N | O |
| Glass | SiO₂ | 42 | 42 | 42 | 44 | 44 | 44 |
| composition | Al₂O₃ | 5 | 5 | 5 | 5 | 5 | 5 |
| (wt %) | B₂O₃ | 5 | 5 | 5 | — | — | — |
| | CaO | 5 | 5 | 5 | 6 | 6 | 6 |
| | SrO | 10 | 10 | 10 | 6 | 6 | 6 |
| | BaO | 28 | 28 | 28 | 26 | 26 | 26 |
| | La₂O₃ | — | — | — | 4.5 | 4.5 | 4.5 |
| | ZrO₂ | 5 | 5 | 5 | 4.5 | 4.5 | 4.5 |
| | TiO₂ | — | — | — | 4 | 4 | 4 |

| | | | | | | |
|---|---|---|---|---|---|---|
| nd | 1.62 | 1.62 | 1.62 | 1.64 | 1.64 | 1.64 |
| Mirror polishing | Mirror | #1,000 | #320 | Mirror | #1,000 | #280 |
| or roughening | polishing | Alumina | Sandblasting | polishing | Alumina | Sandblasting |
| treatment | | polishing | | | polishing | |
| Post-processing | HF | HF | HF | HF | HF | HF |
| Rt (μm) | <1 | 4.8 | 7.2 | <1 | 4.7 | 9.7 |
| RSm (μm) | 25 | 42 | 78 | 41 | 58 | 77 |
| Light extraction | 99% | 113% | 115% | 99% | 109% | 120% |
| efficiency | | | | | | |
| In-plane | 1,450 | 1,100 | 1,100 | 1,400 | 1,050 | 900 |
| strength (MPa) | | | | | | |

Mirror polishing was applied to Sample J by using a cerium-based polishing material having a grain size of #4,000. Alumina polishing was applied to Sample K by using alumina having a grain size of #1,000. Sandblasting was applied to Sample L by blowing, at 2 MPa, a blasting material (prepared by dispersing 4 kg of Al₂O₃ in 20 L of water) having a grain size of #320 onto a surface of the glass substrate.

Next, each of Samples J to L was immersed in an aqueous solution of 5 mass % HF at 25° C. for 30 minutes to perform HF treatment. After the HF treatment, a transparent electrode layer ITO (having a thickness of 100 nm) was formed by vapor deposition on the surface to which roughening treatment had not been applied. After that, predetermined patterning was carried out by using a photomask and hydrochloric acid. Subsequently, a conductive polymer PEDOT-PSS, a hole-transporting layer α-NPD (having a thickness of 60 nm), an organic light-emitting layer also serving as an electron-transporting layer Alq3 (having a thickness of 50 nm), an electron-injecting layer LiF (having a thickness of 1 nm), and a counter electrode Al (having a thickness of 100 nm) were formed, followed by sealing with a metal cap, thus manufacturing each OLED light-emitting device.

<Experiment on Sample No. 5>

First, a glass substrate having the glass composition (No. 5) described in Table 2 and having a thickness of 0.7 mm was prepared. Subsequently, mirror polishing or the roughening treatment (alumina polishing or sandblasting) described in Table 2 was applied to the air-side surface of the glass substrate, followed by the post-processing described in Table 2, yielding Samples M, N, and O.

Mirror polishing was applied to Sample M by using a cerium-based polishing material having a grain size of #4,000. Alumina polishing was applied to Sample N by using alumina having a grain size of #1,000. Sandblasting was applied to Sample O by blowing, at 2 MPa, a blasting material (prepared by dispersing 4 kg of Al₂O₃ in 20 L of water) having a grain size of #280 onto a surface of the glass substrate.

Next, each of Samples M to O was immersed in an aqueous solution of 5 mass % HF at 25° C. for 30 minutes to perform HF treatment. After the HF treatment, a transparent electrode layer ITO (having a thickness of 100 nm) was formed by vapor deposition on the surface to which roughening treatment had not been applied. After that, predetermined patterning was carried out by using a photomask and hydrochloric acid. Subsequently, a conductive polymer PEDOT-PSS, a hole-transporting layer α-NPD (having a thickness of 60 nm), an organic light-emitting layer also serving as an electron-transporting layer Alq3 (having a thickness of 50 nm), an electron-injecting layer LiF (having a thickness of 1 nm), and a counter electrode Al (having a thickness of 100 nm) were formed, followed by sealing with a metal cap, thus manufacturing each OLED light-emitting device.

<Experiment on Sample No. 6>

First, a glass substrate having the glass composition (No. 6) described in Table 3 and having a thickness of 0.5 mm was prepared. Subsequently, mirror polishing or the roughening treatment (alumina polishing or sandblasting) described in Table 3 was applied to the air-side surface of the glass substrate, yielding Samples P, Q, and R.

TABLE 3

| | | No. 6 | | | No. 7 | | |
|---|---|---|---|---|---|---|---|
| | | P | Q | R | S | T | U |
| Glass | SiO₂ | 2 | 2 | 2 | 72 | 72 | 72 |
| composition | Al₂O₃ | 2 | 2 | 2 | 2 | 2 | 2 |
| (wt %) | B₂O₃ | 26.5 | 26.5 | 26.5 | 4 | 4 | 4 |
| | Na₂O | — | — | — | 13 | 13 | 13 |
| | K₂O | — | — | — | 1 | 1 | 1 |
| | CaO | — | — | — | 8 | 8 | 8 |
| | BaO | 3 | 3 | 3 | — | — | — |
| | ZnO | 25 | 25 | 25 | — | — | — |
| | La₂O₃ | 25 | 25 | 25 | — | — | — |
| | Gd₂O₃ | 15 | 15 | 15 | — | — | — |
| | TiO₂ | 1.5 | 1.5 | 1.5 | — | — | — |

| | | | | | | |
|---|---|---|---|---|---|---|
| nd | 1.71 | 1.71 | 1.71 | 1.52 | 1.52 | 1.52 |
| Mirror polishing | Mirror | #1,000 | #600 | Mirror | #1,000 | #600 |
| or roughening | polishing | Alumina | Sandblasting | polishing | Alumina | Sandblasting |
| treatment | | polishing | | | polishing | |
| Post-processing | Absence of | Absence of | Absence of | Absence of | Absence of | Absence of |
| | treatment | treatment | treatment | treatment | treatment | treatment |
| Rt (μm) | <1 | 3.6 | 6.0 | <1 | 4.4 | 8.7 |
| RSm (μm) | 50 | 45 | 66 | 25 | 55 | 64 |
| Light extraction | — | — | — | 100% | 102% | 104% |
| efficiency | | | | | | |
| In-plane | 1,200 | 300 | 100 | 1,400 | 500 | 100 |
| strength (MPa) | | | | | | |

Mirror polishing was applied to Sample P by using a cerium-based polishing material having a grain size of #4,000. Alumina polishing was applied to Sample Q by using alumina having a grain size of #1,000. Sandblasting was applied to Sample R by blowing, at 2 MPa, a blasting material (prepared by dispersing 4 kg of Al₂O₃ in 20 L of water) having a grain size of #600 onto a surface of the glass substrate. Note that post-processing and the manufacture of an OLED device were not carried out for Samples P to R.

<Experiment on Sample No. 7>

First, a glass substrate having the glass composition (No. 7) described in Table 3 and having a thickness of 0.7 mm was prepared. Subsequently, mirror polishing or the roughening treatment (alumina polishing or sandblasting) described in Table 3 was applied to the air-side surface of the glass substrate, followed by the post-processing described in Table 1, yielding Samples S, T, and U.

Mirror polishing was applied to Sample S by using a cerium-based polishing material having a grain size of #4,000. Alumina polishing was applied to Sample T by using alumina having a grain size of #1,000. Sandblasting was applied to Sample U by blowing, at 2 MPa, a blasting material (prepared by dispersing 4 kg of Al₂O₃ in 20 L of water) having a grain size of #600 on a surface of the glass substrate. Note that post-processing was not carried out for Samples S to U.

Next, a transparent electrode layer ITO (having a thickness of 100 nm) was formed by vapor deposition on the surface of each of Samples M to O to which roughening treatment had not been applied. After that, predetermined patterning was carried out by using a photomask and hydrochloric acid. Subsequently, a conductive polymer PEDOT-PSS, a hole-transporting layer α-NPD (having a thickness of 60 nm), an organic light-emitting layer also serving as an electron-transporting layer Alq3 (having a thickness of 50 nm), an electron-injecting layer LiF (having a thickness of 1 nm), and a counter electrode Al (having a thickness of 100 nm) were formed, followed by sealing with a metal cap, thus manufacturing each OLED light-emitting device.

Each of Samples A to U was evaluated for its refractive index nd, surface roughnesses Rt and RSm of a roughened surface, and in-plane strength, and each of Samples A to O and S to U was evaluated for its light extraction efficiency.

The refractive index nd is a value measured with a refractometer KPR-2000 manufactured by Kalnew Optical Industrial Co., Ltd. by using each sample before roughening treatment is applied.

The surface roughnesses Rt and RSm are values measured by a method in conformity with JIS R0601:2001.

The light extraction efficiency is a value evaluated based on the value of the light extraction efficiency of Sample S by using a brightness light distribution characteristics measurement system C9920-11 manufactured by Hamamatsu Photonics K.K.

The in-plane strength is a value measured by a ring-on-ring test. First, each of Samples A to U (whose mirror-polished surface/roughened surface side was positioned downward) after post-processing was placed on a ring-shaped jig with a diameter of 25 mm. Subsequently, a jig with a diameter of 12.5 mm was used to press the sample from the upper side. Specific conditions for the test were as follows: loading machine: strength tester manufactured by Shimadzu Corporation; loading rate: 0.5 mm/min; and press position: center. Finally, the fracture load at which each of Samples A to U was broken was calculated as the in-plane strength.

As evident from Tables 1 to 3, as compared to the samples to which mirror polishing had been applied, in the samples to which roughening treatment had been applied, the surface roughnesses Rt and RSm were so large that the scattering of light at the interface between a glass substrate and air was promoted, and hence the light extraction efficiency was good. Further, a sample having a higher refractive index nd tended to show better light extraction efficiency. Besides, the HF treatment contributed to enhancing the in-plane strength. Note that, though not described in the tables, the surface roughness Rt of the mirror-polished surface of each sample to which mirror polishing is applied and the surface roughness Rt of the surface opposite to the roughened surface of each sample to which roughening treatment is applied are each adjusted to less than 1 nm.

<Additional Experiment on Sample No. 5>

First, a glass substrate having the glass composition (No. 5) described in Table 2 and having a thickness of 0.7 mm was prepared. Subsequently, the roughening treatment (alumina polishing or sandblasting) described in Table 4 was applied to the air-side surface of the glass substrate, followed by, if necessary, the post-processing described in Table 4, yielding Samples a to k. Note that the surface roughness Rt of the surface opposite to the roughened surface is adjusted to less than 1 nm.

TABLE 4

| | | No. 5 | | | | | |
|---|---|---|---|---|---|---|---|
| | | a | b | c | d | e | f |
| Roughening | | #600 | #600 | #600 | #600 | #600 | #600 |
| treatment | | Sandblasting | Sandblasting | Sandblasting | Sandblasting | Sandblasting | Sandblasting |
| Post- | Presence or | Presence | Presence | Presence | Presence | Presence | Presence |
| processsing | absence of | of | of | of | of | of | of |
| | HF | treatment | treatment | treatment | treatment | treatment | treatment |
| | treatment | | | | | | |
| | Treatment | 25 | 25 | 25 | 25 | 25 | 25 |
| | temperature | | | | | | |
| | (° C.) | | | | | | |
| | HF | 1 | 1 | 5 | 5 | 5 | 5 |
| | concentration | | | | | | |
| | (wt %) | | | | | | |
| | Treatment | 1 | 3 | 1 | 3 | 5 | 10 |
| | time | | | | | | |
| | (min) | | | | | | |

| | | | | | | |
|---|---|---|---|---|---|---|
| Rt (μm) | 7.84 | 7.58 | 8.35 | 7.61 | 8.04 | 5.94 |
| RSm (μm) | 58 | 48 | 50 | 61 | 83 | 77 |
| Light extraction | 115% | 117% | 116% | 114% | 112% | 110% |
| efficiency | | | | | | |
| In-plane strength | 600 | 650 | 800 | 820 | 860 | 900 |
| (MPa) | | | | | | |

| | | No. 5 | | | | |
|---|---|---|---|---|---|---|
| | | g | h | i | j | k |
| Roughening | | #600 | #600 | #600 | #400 | #1,200 |
| treatment | | Sandblasting | Sandblasting | Sandblasting | Sandblasting | Alumina |
| | | | | | | polishing |
| Post- | Presence or | Presence | Absence of | Absence of | Presence | Absence of |
| processsing | absence of | of | treatment | treatment | of | treatment |
| | HF | treatment | | | treatment | |
| | treatment | | | | | |
| | Treatment | 25 | — | — | 25 | — |
| | temperature | | | | | |
| | (° C.) | | | | | |
| | HF | 5 | — | — | 5 | — |
| | concentration | | | | | |
| | (wt %) | | | | | |
| | Treatment | 15 | — | — | 10 | — |
| | time | | | | | |
| | (min) | | | | | |

| | | | | | |
|---|---|---|---|---|---|
| Rt (μm) | 6.25 | 6.33 | 8.65 | 9.48 | — |
| RSm (μm) | 85 | 62 | 102 | 124 | — |
| Light extraction | 120% | 118% | 122% | 126% | 107% |
| efficiency | | | | | |
| In-plane strength | 1,170 | 120 | 100 | 920 | 110 |
| (MPa) | | | | | |

Sandblasting was applied to Samples a to j by blowing, at 2 MPa, a blasting material (prepared by dispersing 4 kg of Al₂O₃ in 20 L of water) having a grain size of #600 onto a surface of the glass substrate. Alumina polishing was applied to Sample k by using alumina having a grain size of #1,200.

Subsequently, each of Samples a to g and j was immersed in an HF aqueous solution having the concentration shown in the table and was subjected to HF treatment under the conditions shown in the table. Post-processing was not carried out for Samples h, i, and k. Subsequently, a transparent electrode layer ITO (having a thickness of 100 nm) was formed by vapor deposition on the surface to which roughening treatment had not been applied. After that, predetermined patterning was carried out by using a photomask and hydrochloric acid. Subsequently, a conductive polymer PEDOT-PSS, a hole-transporting layer α-NPD (having a thickness of 60 nm), an organic light-emitting layer also serving as an electron-transporting layer Alq3 (having a thickness of 50 nm), an electron-injecting layer LiF (having a thickness of 1 nm), and a counter electrode Al (having a thickness of 100 nm) were formed, followed by sealing with a metal cap, thus manufacturing each OLED light-emitting device.

Each of Samples a to j was evaluated for its surface roughnesses Rt and RSm of a roughened surface, and each of Samples a to k was evaluated for its light extraction efficiency and in-plane strength.

The surface roughnesses Rt and RSm are values measured by a method in conformity with JIS R0601:2001.

The light extraction efficiency is a value evaluated based on the value of the light extraction efficiency of Sample S in Table 3 by using a brightness light distribution characteristics measurement system C9920-11 manufactured by Hamamatsu Photonics K.K.

The in-plane strength is a value measured by a ring-on-ring test. First, each of Samples a to k (whose roughened surface side was positioned downward) after post-processing was placed on a ring-shaped jig with a diameter of 25 mm. Subsequently, a jig with a diameter of 12.5 mm was used to press the sample from the upper side. Specific conditions for the test were as follows: loading machine: strength tester manufactured by Shimadzu Corporation; loading rate: 0.5 mm/min; and press position: center. Finally, the fracture load at which each of the samples a to k was broken was calculated as the in-plane strength.

### REFERENCE SIGNS LIST

1 glass substrate
2 transparent electrode layer
3 organic light-emitting layer
4 counter electrode

1. A glass substrate for an OLED device, comprising a roughened surface having a surface roughness Rt of from 50 to 10,000 nm as at least one surface thereof, the glass substrate for an OLED device having a refractive index nd of 1.55 or more.

2. A glass substrate for an OLED device, comprising a roughened surface having a surface roughness RSm of from 0.1 to 1,000 μm as at least one surface thereof, the glass substrate for an OLED device having a refractive index nd of 1.55 or more.

3. A glass substrate for an OLED device, comprising a roughened surface having a surface roughness ratio Rt/RSm of from 0.01 to 1 as at least one surface thereof, the glass substrate for an OLED device having a refractive index nd of 1.55 or more.

4. The glass substrate for an OLED device according to claim 1, wherein the roughened surface is formed only as one surface and another surface opposite to the roughened surface has a surface roughness Rt of 10 nm or less.

5. The glass substrate for an OLED device according to claim 1, wherein the roughened surface is formed by physical roughening treatment.

6. The glass substrate for an OLED device according to claim 5, wherein the physical roughening treatment comprises sandblasting treatment.

7. The glass substrate for an OLED device according to claim 5, wherein the physical roughening treatment comprises polishing treatment.

8. The glass substrate for an OLED device according to claim 5, wherein the roughened surface is formed by the physical roughening treatment, followed by chemical solution treatment.

9. The glass substrate for an OLED device according to claim 8, wherein the chemical solution treatment comprises chemical solution treatment with an acid.

10. The glass substrate for an OLED device according to claim 1, wherein the glass substrate for an OLED device comprises from 30 to 70 mass % of SiO₂ as a glass composition.

11. The glass substrate for an OLED device according to claim 1, wherein the glass substrate for an OLED device has an in-plane strength of 150 MPa or more.

12. The glass substrate for an OLED device according to claim 1, wherein the glass substrate for an OLED device is used for an illumination device.

13. An OLED device, comprising the glass substrate for an OLED device according to claim 1.

14. The glass substrate for an OLED device according to claim 2, wherein the roughened surface is formed only as one surface and another surface opposite to the roughened surface has a surface roughness Rt of 10 nm or less.

15. The glass substrate for an OLED device according to claim 3, wherein the roughened surface is formed only as one surface and another surface opposite to the roughened surface has a surface roughness Rt of 10 nm or less.

16. The glass substrate for an OLED device according to claim 2, wherein the roughened surface is formed by physical roughening treatment.

17. The glass substrate for an OLED device according to claim 3, wherein the roughened surface is formed by physical roughening treatment.

18. The glass substrate for an OLED device according to claim 2, wherein the glass substrate for an OLED device comprises from 30 to 70 mass % of SiO₂ as a glass composition.

19. The glass substrate for an OLED device according to claim 3, wherein the glass substrate for an OLED device comprises from 30 to 70 mass % of SiO₂ as a glass composition.

20. The glass substrate for an OLED device according to claim 2, wherein the glass substrate for an OLED device has an in-plane strength of 150 MPa or more.

21. The glass substrate for an OLED device according to claim 3, wherein the glass substrate for an OLED device has an in-plane strength of 150 MPa or more.

22. The glass substrate for an OLED device according to claim 2, wherein the glass substrate for an OLED device is used for an illumination device.

23. The glass substrate for an OLED device according to claim 3, wherein the glass substrate for an OLED device is used for an illumination device.

24. An OLED device, comprising the glass substrate for an OLED device according to claim 2.

25. An OLED device, comprising the glass substrate for an OLED device according to claim 3.
